(19) United States
(12) Patent Application Publication
(10) Pub. No.: US 2026/0117364 A1
(43) Pub. Date: Apr. 30, 2026

(54) DEPOSITION APPARATUS AND METHOD OF MANUFACTURING ELECTRONIC DEVICE USING THE SAME

(71) Applicant: Samsung Display Co., Ltd., Yongin-Si (KR)

(72) Inventors: INTAEK YOON, Yongin-si (KR); SUNGJONG PARK, Yongin-si (KR); JONGBUN HAN, Yongin-si (KR)

(21) Appl. No.: 19/318,716

(22) Filed: Sep. 4, 2025

(30) Foreign Application Priority Data
Oct. 31, 2024 (KR) 10-2024-0152662

(51) Int. Cl. C23C 14/24; C23C 14/04; C23C 14/50; C23C 14/54

(52) U.S. Cl. CPC C23C 14/24; C23C 14/042; C23C 14/50; C23C 14/54

(57) ABSTRACT

A deposition apparatus includes a chamber having an inner space and a deposition module disposed in the inner space, movable in a first direction, and including a first deposition source, a second deposition source, a third deposition source, an angle restriction plate through which a first opening overlapping the first deposition source when viewed in a plane, a second opening overlapping the second deposition source when viewed in the plane and including an open area and a block area, and a third opening overlapping the third deposition source when viewed in the plane are defined, and a shutter configured to operate in a block mode to block the block area and the first opening, and in an open mode to open the first opening and the second opening.

### CROSS-REFERENCE TO RELATED APPLICATION(S)

This application claims priority to and the benefit of Korean Patent Application No. 10-2024-0152662, filed on Oct. 31, 2024 in the Korean Intellectual Property Office, the disclosure of which is incorporated by reference herein in its entirety.

### BACKGROUND

### 1. Field

The present disclosure relates to a deposition apparatus and a method of manufacturing an electronic device using the same. More particularly, the present disclosure relates to a deposition apparatus that forms a mixed layer in the manufacture of an electronic device and a method of manufacturing the electronic device using the deposition apparatus.

### 2. Description of Related Art

An electronic device, such as a smart phone, a digital camera, a notebook computer, a navigation device, and a smart television, generates images and provides the images to a user through a display screen.

The electronic device is manufactured through various processes. As an example, the electronic device is manufactured through a deposition process, an etching process, a cleaning process, and the like, which are performed on a substrate. In the deposition process, a deposition layer may be formed on a surface of a target substrate by heating a deposition source.

### SUMMARY

The present disclosure provides a deposition apparatus capable of forming a deposition pattern in which two types of mixed layers are sequentially stacked.

The present disclosure provides a method of manufacturing an electronic device to form the deposition pattern including two types of mixed layers using the deposition apparatus.

An embodiment of a deposition apparatus includes a chamber having an inner space and a deposition module disposed in the inner space, movable in a first direction, and including a first deposition source, a second deposition source, a third deposition source, an angle restriction plate through which a first opening overlapping the first deposition source when viewed in a plane, a second opening overlapping the second deposition source when viewed in the plane and including an open area and a block area, and a third opening overlapping the third deposition source when viewed in the plane are defined, and a shutter configured to operate in a block mode to block the block area and the first opening, and in an open mode to open the first opening and the second opening.

In an embodiment, the second opening has a width greater than a width of the first opening and a width of the third opening when viewed in a cross-section.

In an embodiment, the first, second, and third deposition sources include first, second, and third deposition materials, respectively. A second discharge angle at which the second deposition material passes through the second opening may be greater than a first discharge angle at which the first deposition material passes through the first opening and a third discharge angle at which the third deposition material passes through the third opening.

In an embodiment, the first deposition source, the second deposition source, and the third deposition source are sequentially arranged in the first direction.

In an embodiment, the block area is defined closer to the first opening than the opening area.

In an embodiment, the second deposition material is different from the first deposition material and the third deposition material.

In an embodiment, the first deposition material includes a first host material, the second deposition material includes a dopant material, and the third deposition material includes a second host material.

In an embodiment, the first deposition source includes a first body part and a first nozzle disposed on the first body part, the second deposition source includes a second body part and a second nozzle disposed on the second body part, and the third deposition source includes a third body part and a third nozzle disposed on the third body part.

In an embodiment, the shutter has a block plate shape that is movable in the first direction, and when the shutter operates in the block mode, the shutter blocks the block area and the first opening.

In an embodiment, the shutter is slidable in the first direction.

In an embodiment, the shutter includes a block plate that is movable in the first direction and a rotation plate that is attached to the angle restriction plate, and when the shutter operates in the block mode, the block plate blocks the first opening, and the rotation plate blocks the block area.

In an embodiment, the second opening includes a second-first opening overlapping the open area and a second-second opening spaced apart from the second-first opening and overlapping the block area when viewed in the plane.

An embodiment of a deposition apparatus includes a chamber having an inner space and a deposition module disposed in the inner space, movable in a first direction, and including a first deposition source, a second deposition source, a third deposition source, a fourth deposition source, an angle restriction plate through which first, second, third, and fourth openings respectively overlapping the first, second, third, and fourth deposition sources when viewed in a plane are defined, and a shutter configured to operate in a block mode to block the first opening and the second opening, and in an open mode to open the first opening and the second opening.

In an embodiment, the shutter has a block plate shape that is movable in the first direction, and the shutter is slidable in the first direction.

An embodiment of a method of manufacturing an electronic device includes providing a deposition module including first, second, and third deposition sources sequentially arranged in one direction, an angle restriction plate through which first, second, and third openings respectively overlapping the first, second, and third deposition sources when viewed in a plane are defined, and a shutter blocking a deposition process by the first and second deposition sources, placing a target substrate above the deposition module, operating the deposition module to form a first mixed layer including a first deposition material provided from the first deposition source and a second deposition material provided from the second deposition source on a rear surface of the target substrate, to form a second-first mixed layer including the second deposition material and a third deposition material provided from the third deposition source on a rear surface of the first mixed layer, and to move in a direction opposite to the one direction, and operating the shutter to block a portion of the second opening and the first opening and allowing the deposition module to form a second-second mixed layer including the second deposition material provided from the second deposition source and the third deposition material provided from the third deposition source on a rear surface of the second-first mixed layer and to move in the one direction.

In an embodiment, the method further includes allowing the shutter to block the portion of the second opening and the first opening and allowing the deposition module to form the second-second mixed layer including the second deposition material provided from the second deposition source and the third deposition material provided from the third deposition source on the rear surface of the second-first mixed layer and to move in the one direction between the placing of the target substrate above the deposition module and the moving of the deposition module in the direction opposite to the one direction.

In an embodiment, the first deposition source includes a first nozzle facing the target substrate, and when the moving of the deposition module in the direction opposite to the one direction starts, the first nozzle is positioned in the one direction beyond a side surface of the target substrate adjacent to the first nozzle.

In an embodiment, the second opening has a width greater than a width of the first opening and a width of the third opening when viewed in a cross-section, and a second discharge angle at which the second deposition material passes through the second opening is greater than a first discharge angle at which the first deposition material passes through the first opening and a third discharge angle at which the third deposition material passes through the third opening.

Areas where the first, second, and third deposition materials are deposited on the rear surface of the target substrate after respectively passing through the first, second, and third openings may be defined as first, second, and third deposition areas, respectively, in the moving of the deposition module in the direction opposite to the one direction, the second deposition area overlaps the first deposition area and the third deposition area, and the first deposition area is spaced apart from the third deposition area with a gap.

The second deposition area formed by the second deposition material passing through the second opening may overlap the third deposition area formed by the third deposition material passing through the third opening in the moving of the deposition module in the one direction.

An embodiment of an electronic device includes a display panel, which includes pixels, a window disposed on the display panel, and a housing disposed on a rear surface of the display panel. Each of the pixels includes a display element including a light emitting layer and a pixel driving circuit. The light emitting layer is formed by providing a deposition module including first, second, and third deposition sources sequentially arranged in one direction, an angle restriction plate through which first, second, and third openings respectively overlapping the first, second, and third deposition sources when viewed in a plane are defined, and a shutter blocking a deposition process by the first and second deposition sources, placing a target substrate above the deposition module, operating the deposition module to form a first mixed layer including a first deposition material provided from the first deposition source and a second deposition material provided from the second deposition source on a rear surface of the target substrate, to form a second-first mixed layer including the second deposition material and a third deposition material provided from the third deposition source on a rear surface of the first mixed layer, and to move in a direction opposite to the one direction, and operating the shutter to block a portion of the second opening and the first opening and allowing the deposition module to form a second-second mixed layer including the second deposition material provided from the second deposition source and the third deposition material provided from the third deposition source on a rear surface of the second-first mixed layer and to move in the one direction.

In an embodiment, the second deposition material is different from the first deposition material and the third deposition material.

In an embodiment, the first deposition material includes a first host material, the second deposition material includes a dopant material, and the third deposition material includes a second host material.

According to an embodiment of the deposition apparatus, a deposition pattern in which two types of mixed layers are sequentially stacked is formed by the deposition apparatus.

According to an embodiment of the method of manufacturing the electronic device, the two types of mixed layers are sequentially stacked by one reciprocating movement. Accordingly, a manufacturing process to form the electronic device is simplified, and the cost and time required for a deposition process are reduced.

### BRIEF DESCRIPTION OF THE DRAWINGS

FIG. 1 is a cross-sectional view illustrating a deposition apparatus according to an embodiment of the present disclosure.

FIG. 2 is a plan view illustrating a deposition module according to an embodiment of the present disclosure.

FIG. 3 is a flowchart illustrating a method of manufacturing an electronic device according to an embodiment of the present disclosure.

FIGS. 4, 5, 6, 7, 8, and 9 are views illustrating processes of a method of manufacturing an electronic device according to an embodiment of the present disclosure.

FIG. 10 is an enlarged cross-sectional view illustrating an area AA′ of FIG. 9.

FIG. 11 is a flowchart illustrating a method of manufacturing an electronic device according to an embodiment of the present disclosure.

FIG. 12 is an enlarged cross-sectional view illustrating a deposition pattern according to an embodiment of the present disclosure.

FIGS. 13A and 13B are cross-sectional views illustrating a deposition module according to an embodiment of the present disclosure.

FIGS. 14A and 14B are cross-sectional views illustrating a deposition module according to an embodiment of the present disclosure.

FIGS. 15A and 15B are cross-sectional views illustrating a deposition module according to an embodiment of the present disclosure.

FIG. 16 is an enlarged cross-sectional view illustrating a deposition pattern according to an embodiment of the present disclosure.

FIG. 17A is a perspective view illustrating an electronic device manufactured through a manufacturing method of the electronic device according to an embodiment of the present disclosure.

FIG. 17B is an exploded perspective view illustrating an electronic device manufactured through a manufacturing method of the electronic device according to an embodiment of the present disclosure.

FIG. 17C is a cross-sectional view illustrating one pixel included in an electronic device.

FIG. 17D is a block diagram illustrating an electronic device according to an embodiment of the present disclosure.

FIG. 18 is a cross-sectional view illustrating a deposition process performed by the deposition apparatus of FIG. 1.

### DETAILED DESCRIPTION

The present disclosure may be variously modified and realized in many different forms, and thus specific embodiments will be exemplified in the drawings and described in detail hereinbelow. However, the present disclosure should not be limited to the specific disclosed forms, and be construed to include all modifications, equivalents, or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “comprise” and “include” (as well as variations such as “including”), when used in this specification, specify the presence of stated features, integers, steps, operations, elements, or components, but do not preclude the presence or addition of one or more other features, integers, steps, operations, elements, components, or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

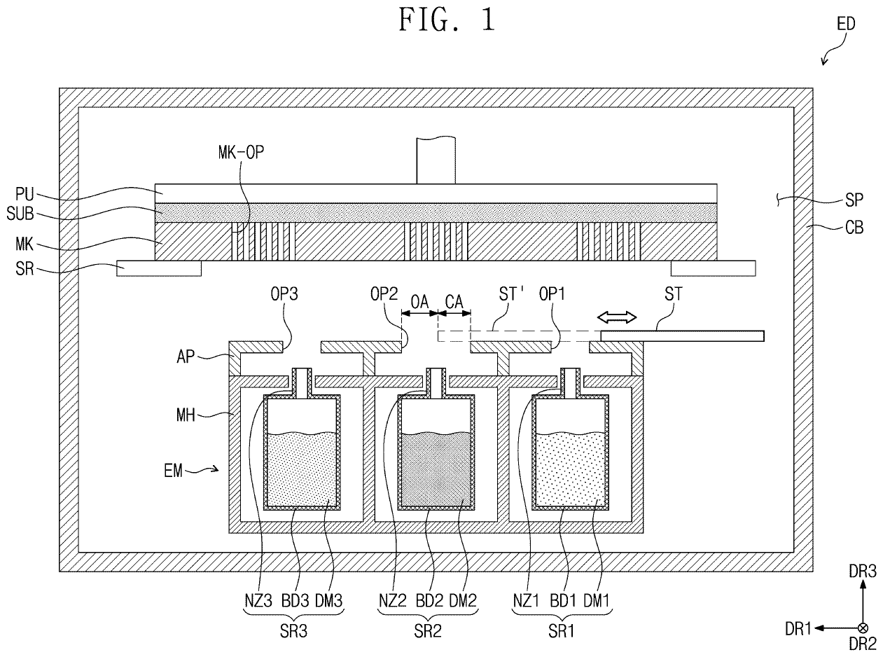

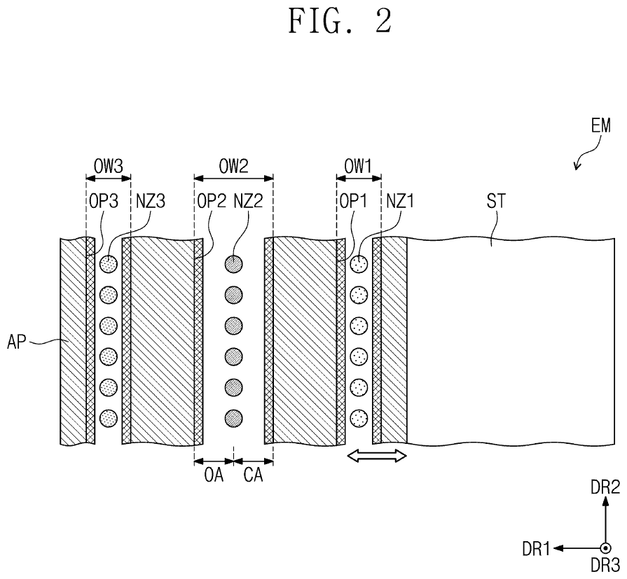

FIG. 1 is a cross-sectional view illustrating a deposition apparatus according to an embodiment of the present disclosure. FIG. 2 is a plan view illustrating a deposition module according to an embodiment of the present disclosure.

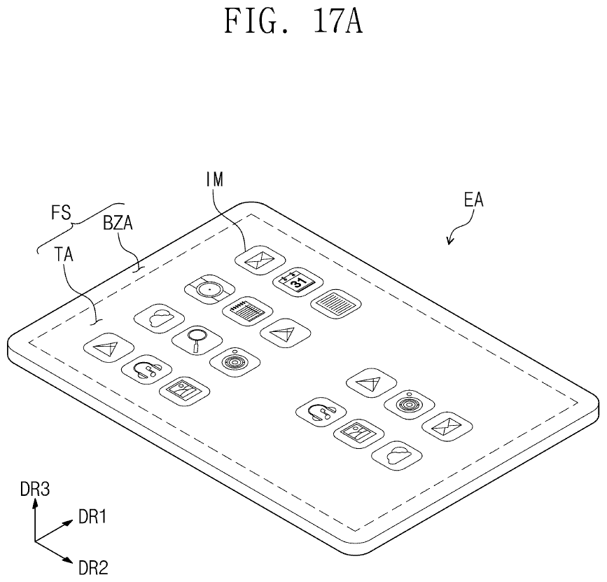

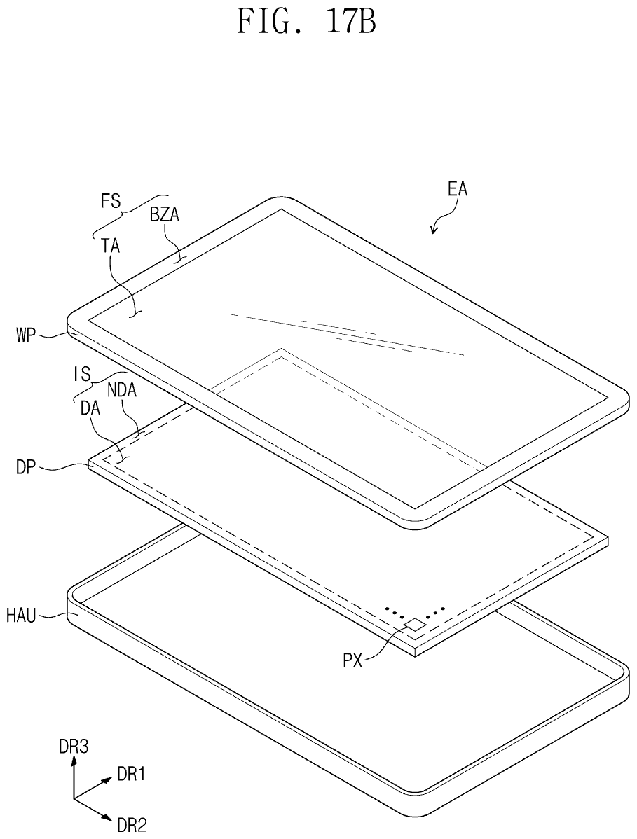

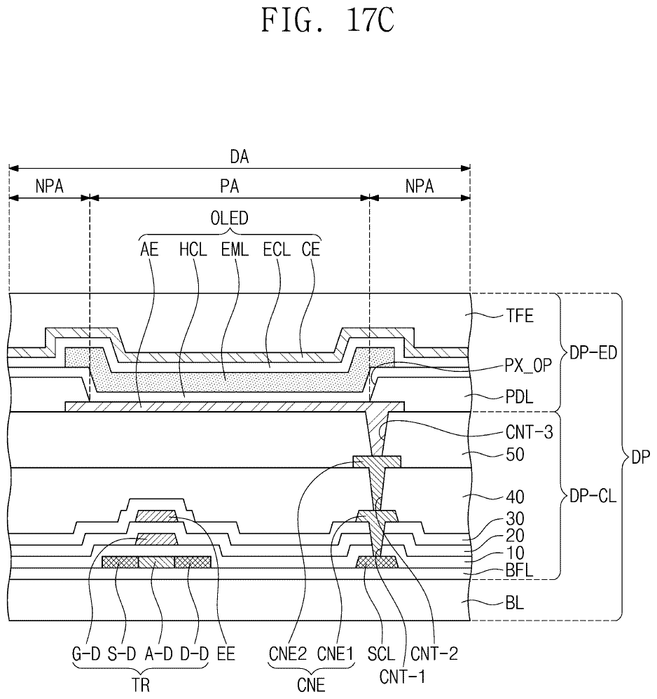

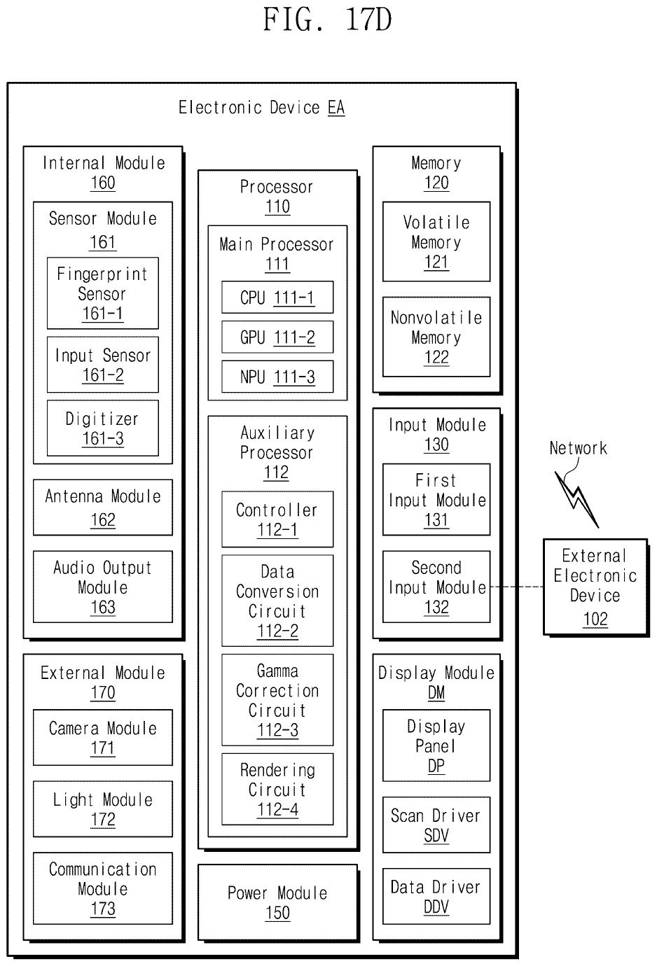

The deposition apparatus ED according to the present disclosure may be used to form one or more of functional layers included in an electronic device. As an example, the deposition apparatus ED may be used to form a deposition pattern (refer to EML of FIG. 17C) on a substrate included in the electronic device.

Referring to FIG. 1, the deposition apparatus ED may include a chamber CB, a fixing unit PU, a mask MK, a stage SR, and the deposition module EM. The deposition apparatus ED may further include additional mechanical apparatuses to implement an inline system.

The chamber CB may provide an inner space SP. The inner space SP of the chamber CB may be defined by a bottom surface, a ceiling surface, and sidewalls connecting the bottom surface and the ceiling surface of the chamber CB. The bottom surface of the chamber CB may be substantially parallel to a plane defined by a first direction DR1 and a second direction DR2, and a normal line direction of the bottom surface of the chamber CB may be substantially parallel to a third direction DR3. In the present disclosure, the expression “when viewed in the plane” may be defined based on a surface parallel to the plane defined by the first direction DR1 and the second direction DR2.

The inner space SP of the chamber CB may an enclosed space. Accordingly, the chamber CB may set a deposition condition inside the chamber CB to a vacuum state.

Although not shown in figures, the chamber CB may include one or more gates. The chamber CB may be opened or closed by the gate. The deposition module EM and a target substrate SUB, which are provided in the inner space SP of the chamber CB, may enter and exit through the gate provided in the chamber CB.

The fixing unit PU may be placed above the deposition module EM in the chamber CB. The fixing unit PU may function to attach the mask MK to the target substrate SUB. FIG. 1 illustrates a structure in which the mask MK is in contact with the target substrate SUB as a representative example. However, the present disclosure should not be limited thereto or thereby, and the mask MK may be spaced apart from the target substrate SUB with a gap without being in contact with the target substrate SUB.

The fixing unit PU may include a magnetic material to secure the mask MK to the target substrate SUB. According to an embodiment, the fixing unit PU may include an electro-static chuck. The fixing unit PU may apply an attractive force to the mask MK to prevent the mask MK from sagging due to gravity.

Although not shown in figures, the fixing unit PU may further include a holding part to hold the target substrate SUB. The holding part may function to keep the target substrate SUB stationary during the deposition process. As an example, the holding part may be defined as a groove to which the target substrate SUB is detachably coupled.

The target substrate SUB may be a processing target on which deposition materials DM1, DM2, and DM3 are deposited. As an example, the target substrate SUB may include a support substrate and a synthetic resin layer disposed on the support substrate and corresponding to a base substrate (refer to BL of FIG. 17C). The support substrate may be removed in a manufacturing process of the electronic device. Depending on the component formed through the deposition process, the target substrate SUB may include some components of the electronic device formed on the base substrate (refer to BL of FIG. 17C).

The mask MK may be disposed on the stage SR described later. The mask MK may be disposed between the deposition module EM and the target substrate SUB. As an example, the mask MK may be fixed to the stage SR and may be attached to and detached from the stage SR. An upper surface of the mask MK may face the target substrate SUB.

In the present embodiment, the mask MK may be a fine metal mask (FMM) or a fine silicon mask (FSM). However, materials and types of the mask MK should not be particularly limited as long as the mask MK may be used in a substrate deposition process.

The stage SR may be disposed between the deposition module EM and the fixing unit PU. The stage SR may be placed outside a movement path of the deposition materials DM1, DM2, and DM3 supplied from the deposition module EM toward the target substrate SUB.

The stage SR may support the mask MK. The stage SR may provide a seating surface on which the mask MK is placed. The seating surface may be substantially parallel to the first direction DR1 and the second direction DR2. The seating surface of the stage SR may be substantially parallel to the bottom surface of the chamber CB.

The deposition module EM may be placed in the inner space SP of the chamber CB to face the fixing unit PU. For the convenience of explanation, In FIG. 1, the size of the deposition module EM is exaggerated for illustrative purposes, but the embodiment of the present disclosure should not be limited to the depicted configuration. As an example, the deposition module EM may have a size small enough to perform a reciprocating movement, which will be described later, in the inner space SP of chamber CB.

Although not shown in figures, the deposition module EM may be connected to a driving device. Accordingly, the deposition module EM may perform a deposition process while moving. The deposition module EM may move along the first direction DR1.

The deposition module EM may include a module housing MH, first, second, and third deposition sources SR1, SR2, and SR3, an angle restriction plate AP, and a shutter ST.

The module housing MH may surround the first, second, and third deposition sources SR1, SR2, and SR3. The first, second, and third deposition sources SR1, SR2, and SR3 may be arranged in the module housing MH. However, the present disclosure should not be limited thereto or thereby, and according to an embodiment, the first, second, and third deposition sources SR1, SR2, and SR3 may be provided while being coupled to each other without the module housing.

The first deposition source SR1 may include a first body part BD1, a first nozzle NZ1 disposed on the first body part BD1, and a first deposition material DM1 disposed in the first body part BD1.

The second deposition source SR2 may include a second body part BD2, a second nozzle NZ2 disposed on the second body part BD2, and a second deposition material DM2 disposed in the second body part BD2.

The third deposition source SR3 may include a third body part BD3, a third nozzle NZ3 disposed on the third body part BD3, and a third deposition material DM3 disposed in the third body part BD3.

The first, second, and third deposition materials DM1, DM2, and DM3 may include an inorganic material, a metal material, or an organic material that is able to sublimate or vaporize.

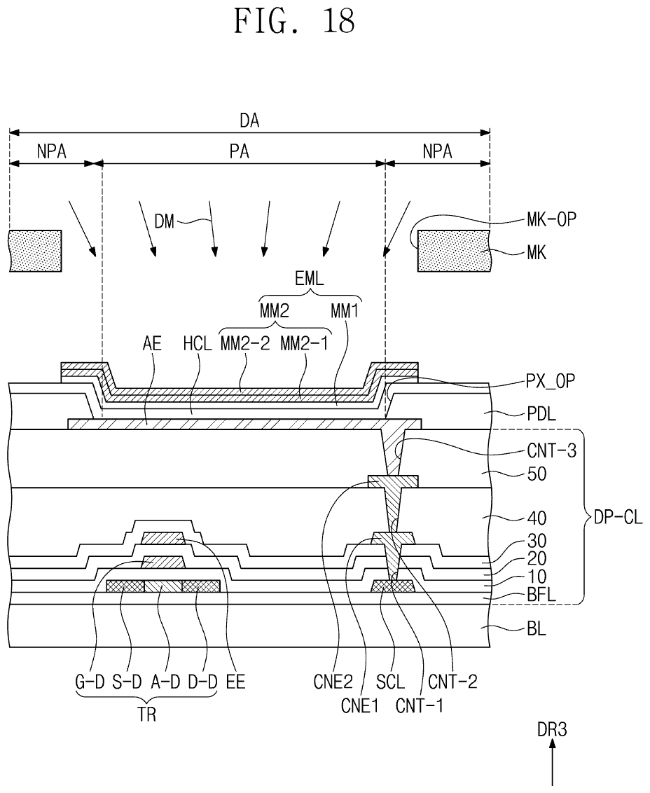

In the present embodiment, the first, second, and third deposition materials DM1, DM2, and DM3 may include materials to form the deposition pattern EML (refer to FIG. 18).

As an example, the first, second, and third deposition materials DM1, DM2, and DM3 may include a light emitting material to form a light emitting layer of a light emitting element.

The second deposition material DM2 may include a material different from the first deposition material DM1 and the third deposition material DM3. In detail, the first deposition material DM1 may include a first host material, the second deposition material may include a dopant material, and the third deposition material may include a second host material.

Although not shown in figures, a heating part (not shown) may be provided in each of the first, second, and third deposition sources SR1, SR2, and SR3. Accordingly, the first, second, and third deposition materials DM1, DM2, and DM3 may be sublimated or vaporized. However, the present disclosure should not be limited thereto or thereby, and according to an embodiment, the heating parts (not shown) may be disposed between the module housing MH and the first, second, and third deposition sources SR1, SR2, and SR3.

The first, second, and third deposition materials DM1, DM2, and DM3 may be discharged to the outside through the first, second, and third nozzles NZ1, NZ2, and NZ3, respectively. The first, second, and third deposition materials DM1, DM2, and DM3 may be deposited on a rear surface of the target substrate SUB in a selected pattern through a mask opening MK-OP defined through the mask MK. As used herein, the rear surface refers to the surface facing downward toward the first, second, and third deposition sources SR1, SR2, and SR3.

The angle restriction plate AP may be disposed above the first, second, and third deposition sources SR1, SR2, and SR3.

First, second, and third openings OP1, OP2, and OP3 may be defined through the angle restriction plate AP.

When viewed in the plane, the first opening OP1 may overlap the first deposition source SR1, the second opening OP2 may overlap the second deposition source SR2, and the third opening OP3 may overlap the third deposition source SR3.

An open area OA and a block area CA may be defined to correspond to the second opening OP2. The open area OA may be defined as an area that is not blocked by the shutter ST. The block area CA may be defined as an area that is blocked by the shutter ST when the shutter ST operates in a block mode. The block area CA may be closer to the first opening OP1 than the open area OA is.

The angle restriction plate AP may control an angle at which each of the deposition materials DM1, DM2, and DM3 is discharged to the outside of the deposition module EM. In detail, the angle restriction plate AP may block a portion of each of the deposition materials DM1, DM2, and DM3, which is discharged at a certain angle or greater, and thus, the angle at which the deposition materials DM1, DM2, and DM3 are discharged may be controlled. Accordingly, a selected pattern may be formed in the rear surface of the target substrate SUB, and the deposition process will be described later.

The shutter ST may be disposed on the angle restriction plate AP.

The shutter ST may block the first opening OP1 and a portion of the second opening OP2 and thus may function to control the discharge of the first deposition material DM1 and the deposition range of the second deposition material DM2.

The shutter ST may operate in the block mode to block the first opening OP1 and the portion of the second opening OP2 or may operate in an open mode to open the first opening OP1 and the second opening OP2.

FIG. 1 illustrates a position of the shutter ST in the open mode. In addition, a position ST′ of the shutter ST when the shutter ST moves to operate in the block mode is indicated by a quadrangular shape with a dotted line. The operation and function of the shutter ST will be described later.

In the present embodiment, the shutter ST may have a block plate shape that is movable in the first direction DR1. In detail, the shutter ST may slide in the first direction DR1. When the shutter ST operates in the block mode, the shutter ST may block the block area CA and the first opening OP1.

Referring to FIG. 2, the deposition module EM according to the present embodiment may be a linear deposition module to perform a linear deposition. That is, each of the nozzles NZ1, NZ2, and NZ3 may be linearly arranged along the second direction DR2.

The second opening OP2 may have a width OW2 greater than a width OW1 of the first opening OP1 and a width OW3 of the third opening OP3.

Accordingly, the second deposition material DM2 may be discharged at a discharge angle greater than the third deposition material DM3 and the first deposition material DM1. This will be described later.

According to a conventional deposition apparatus, when a deposition process is performed using deposition materials discharged from separate deposition sources, a single layer and a mixed layer are alternately deposited.

Unlike the conventional deposition apparatus, the deposition apparatus ED according to the present disclosure may alternately deposit mixed layers on the rear surface of the target substrate SUB using the deposition materials DM1, DM2, and DM3 respectively discharged from the deposition sources SR1, SR2, and SR3.

In detail, the deposition apparatus ED according to the present embodiment may alternately deposit a mixed layer including the second deposition material DM2 and the first deposition material DM1 and a mixed layer including the second deposition material DM2 and the third deposition material DM3. Accordingly, the efficiency of the deposition process may be improved, and thus, the cost and time required for the deposition process may be reduced.

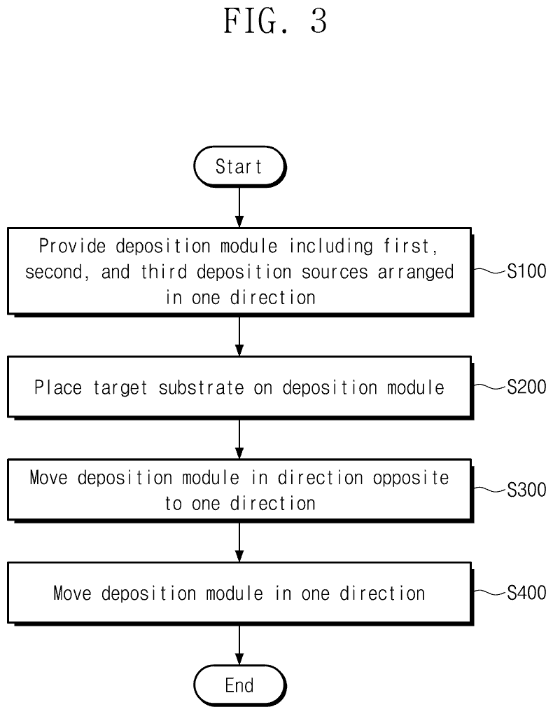

FIG. 3 is a flowchart illustrating a method of manufacturing the electronic device according to an embodiment of the present disclosure.

Referring to FIG. 3, the manufacturing method of the electronic device according to the present disclosure may include providing the deposition module including the first to third deposition sources arranged in one direction (S100), placing the target substrate above the deposition module (S200), moving the deposition module in a direction opposite to the one direction (S300), and moving the deposition module in the one direction (S400).

Although not shown in figures, the manufacturing method of the electronic device according to the present disclosure may further include moving the deposition module in the direction opposite to the one direction and moving the deposition module in the one direction. Accordingly, a third mixed layer and a fourth mixed layer may be formed on a rear surface of a second mixed layer described later. The third mixed layer may include the first deposition material and the second deposition material, and the fourth mixed layer may include the second deposition material and the third deposition material.

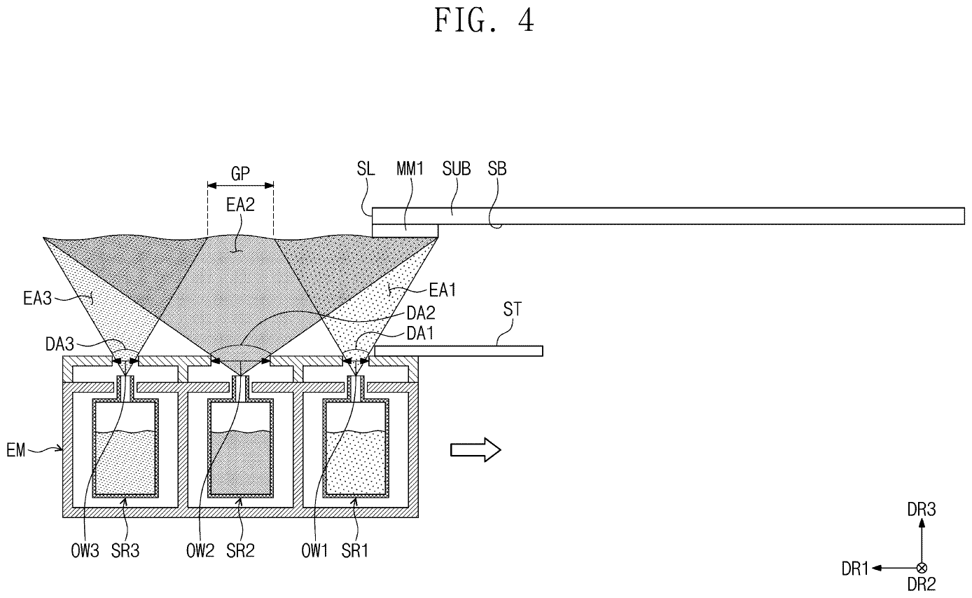

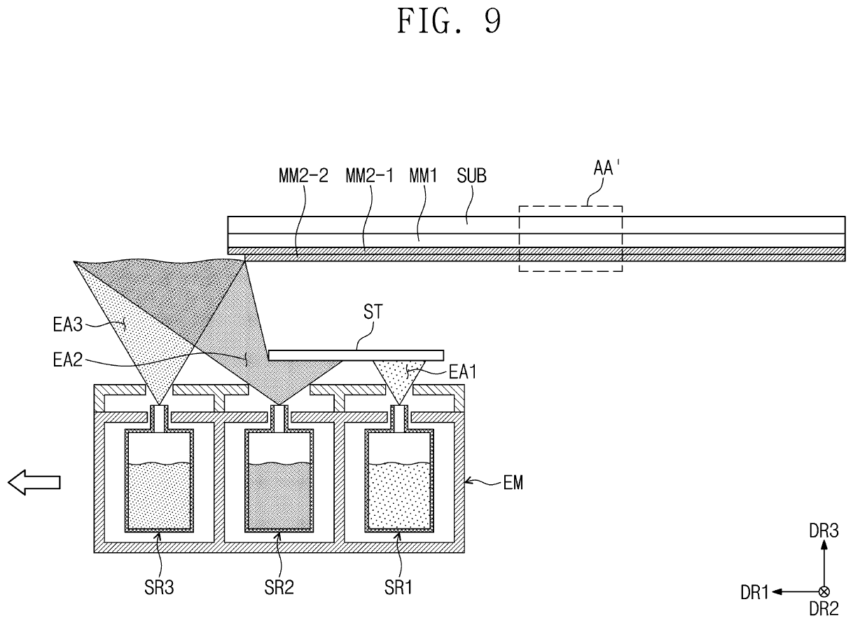

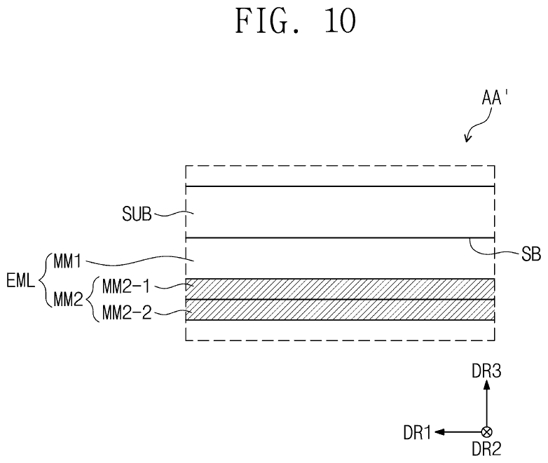

FIGS. 4 to 9 are views illustrating processes of the manufacturing method of the electronic device according to an embodiment of the present disclosure. FIG. 10 is an enlarged cross-sectional view illustrating an area AA′ of FIG. 9.

Hereinafter, the manufacturing method of the electronic device using the deposition apparatus ED (refer to FIG. 1) will be described with reference to FIGS. 4 to 10.

In FIGS. 4 to 9, for the convenience of explanation, components such as the chamber CB (refer to FIG. 1) included in the deposition apparatus ED (refer to FIG. 1) are omitted except for the deposition module EM and the target substrate SUB.

FIG. 4 illustrates a state in which the providing of the deposition module EM (S100, refer to FIG. 3) and the placing of the target substrate SUB (S200, refer to FIG. 3) are performed.

In the present embodiment, the first, second, and third deposition sources SR1, SR2, and SR3 may be sequentially arranged in one direction. Then, the moving of the deposition module in the direction opposite to the one direction (S300, refer to FIG. 3) may be performed. As an example, the first, second, and third deposition sources SR1, SR2, and SR3 may be sequentially arranged in a left direction, and the deposition module EM may move in a right direction. In the present disclosure, the moving of the deposition module EM in the right direction may be expressed as a first movement of the deposition module EM.

FIG. 4 illustrates the shutter ST that operates in the open mode.

When the moving of the deposition module in the opposite direction to the one direction (S300, refer to FIG. 3) starts, the first nozzle NZ1 included in the first deposition source SR1 may be disposed at the one direction with respect to a side surface SL of the target substrate, which is adjacent to the deposition module EM. FIG. 4 shows the state in which the first nozzle NZ1 is disposed at the left direction with respect to the side surface SL of the target substrate, which is adjacent to the deposition module EM.

The deposition materials DM1, DM2, and DM3 may be discharged from the first, second, and third deposition sources SR1, SR2, and SR3, respectively.

In the present disclosure, an area formed under the target substrate SUB in an area to which the first deposition material DM1 (refer to FIG. 1) discharged from the first nozzle NZ1 is sprayed is referred to as a first deposition area EA1, an area formed under the target substrate SUB in an area to which the second deposition material DM2 (refer to FIG. 1) discharged from the second nozzle NZ2 is sprayed is referred to as a second deposition area EA2, and an area formed under the target substrate SUB in an area to which the third deposition material DM3 (refer to FIG. 1) discharged from the third nozzle NZ3 is sprayed is referred to as a third deposition area EA3.

When viewed in a cross-section, an angle at which the first deposition material DM1 (refer to FIG. 1) is discharged through the first opening OP1 after passing through the first nozzle NZ1 is referred to as a first discharge angle DA1, an angle at which the second deposition material DM2 (refer to FIG. 1) is discharged through the second opening OP2 after passing through the second nozzle NZ2 is referred to as a second discharge angle DA2, and an angle at which the third deposition material DM3 (refer to FIG. 1) is discharged through the third opening OP3 after passing through the third nozzle NZ3 is referred to as a third discharge angle DA3.

In the present embodiment, since the width OW2 of the second opening is greater than the width OW1 of the first opening and the width OW3 of the third opening, the second discharge angle DA2 may be greater than the first discharge angle DA1 and the third discharge angle DA3. Accordingly, the second deposition area EA2 may be defined greater than the first deposition area EA1 and the third deposition area EA3.

The second deposition area EA2 may overlap the first deposition area EA1 and the third deposition area EA3. Accordingly, a first mixed layer MM1 including the second deposition material DM2 and the first deposition material DM1 may be formed, and a second-first mixed layer MM2-1 including the second deposition material DM2 and the third deposition material DM3 may be formed.

However, the first deposition area EA1 may not overlap the third deposition area EA3. The first deposition area EA1 and the third deposition area EA3 may be spaced apart from each other with a gap GP. Therefore, the first deposition material DM1 and the third deposition material DM3 may be prevented from being mixed with each other.

Referring to FIG. 4, the first mixed layer MM1 may be formed on the rear surface SB of the target substrate SUB in an area where the first deposition area EA1 overlaps the second deposition area EA2.

In the present embodiment, the deposition module EM may form the first mixed layer MM1 while moving in the right direction.

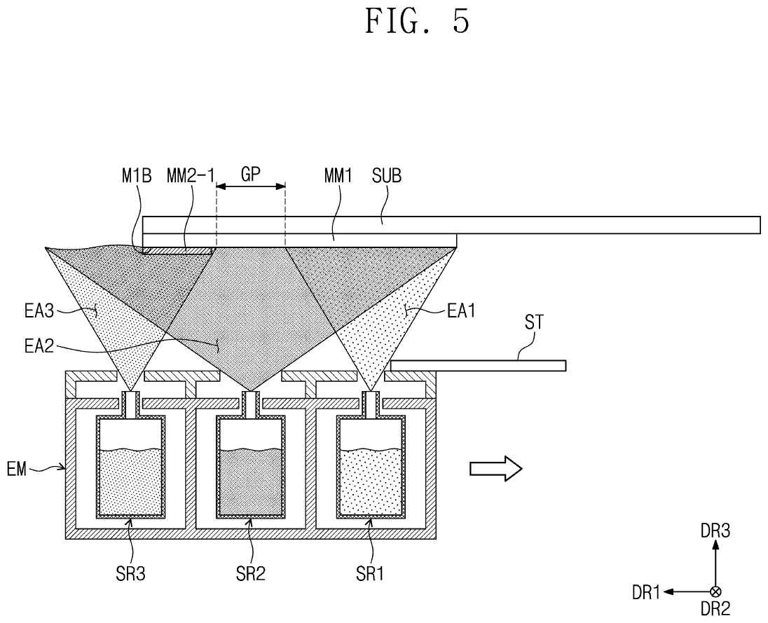

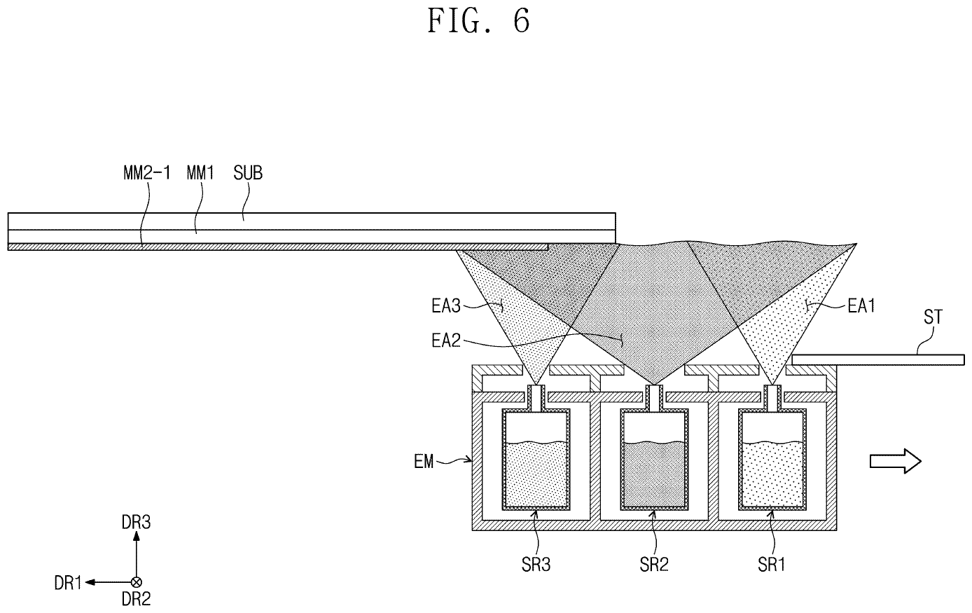

Then, referring to FIGS. 5 and 6, the deposition module EM may form the first mixed layer MM1 in the area where the first deposition area EA1 overlaps the second deposition area EA2 and may simultaneously form the second-first mixed layer MM2-1 in an area where the second deposition area EA2 overlaps the third deposition area EA3.

The second-first mixed layer MM2-1 may be formed in a portion where the first mixed layer MM1 is already formed. Accordingly, the second-first mixed layer MM2-1 may be formed on a rear surface M1B of the first mixed layer MM1.

The second-first mixed layer MM2-1 may be in contact with the rear surface M1B of the first mixed layer MM1.

The first mixed layer MM1 and the second-first mixed layer MM2-1 may be sequentially stacked in a downward direction away from the target substrate SUB.

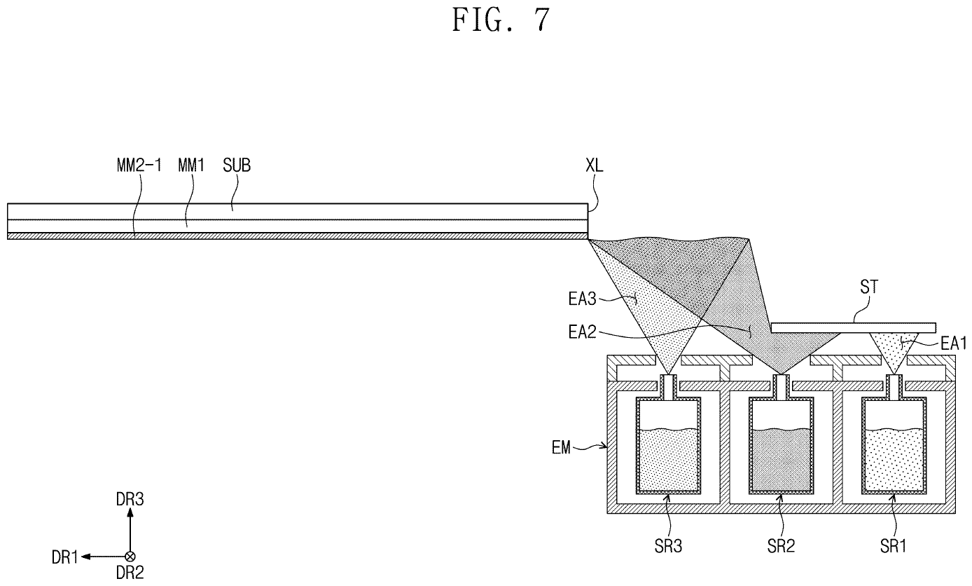

Referring to FIG. 7, when the deposition module EM overlaps the other side surface XL opposite to the one side surface SL of the target substrate SUB or moves in a right direction of the other side surface XL when viewed in the plane, the first mixed layer MM1 and the second-first mixed layer MM2-1 may be fully formed on the rear surface of the target substrate SUB.

Then, the operation of the shutter ST may be switched to the block mode. That is, the shutter ST may block the first deposition area EA1 formed by the deposition material discharged through the first opening OP1 and the portion of the second deposition area EA2 formed by the deposition material discharged through the block area CA.

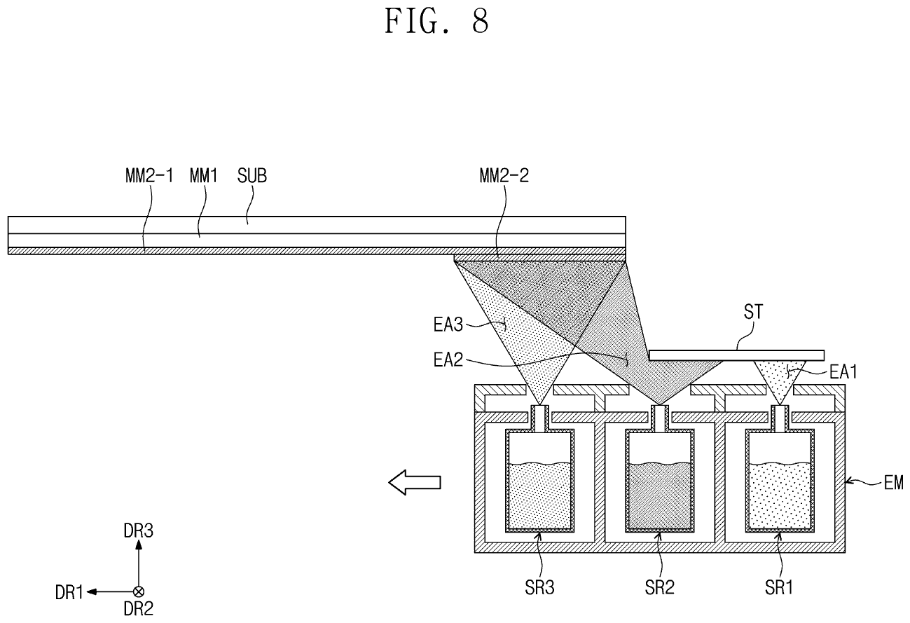

Referring to FIGS. 8 and 9, the moving of the deposition module EM in the opposite direction to the one direction (S300, refer to FIG. 3) may be performed. As an example, the deposition module EM may move in the left direction. In the present disclosure, the moving of the deposition module EM in the left direction may be referred to as a second movement of the deposition module EM.

Accordingly, a second-second mixed layer MM2-2 may be formed on a rear surface of the second-first mixed layer MM2-1. The second-second mixed layer MM2-2 may include the second deposition material DM2 and the third deposition material DM3.

In this case, since the shutter ST operates in the block mode, the second-second mixed layer MM2-2 may be formed while the deposition module EM moves in the opposite direction to the one direction.

Referring to FIG. 10, the deposition pattern EML may be formed on the rear surface of the target substrate SUB through the manufacturing method of the electronic device. One deposition pattern EML may be formed by performing one first movement followed by one second movement of the deposition module EM (refer to FIG. 1). In the present disclosure, one first movement and one second movement of the deposition module EM (refer to FIG. 1) may be referred to as one reciprocating movement of the deposition module EM.

The deposition pattern EML may include the first mixed layer MM1 and the second mixed layer MM2, which are sequentially stacked.

The second mixed layer MM2 may include the second-first mixed layer MM2-1 and the second-second mixed layer MM2-2. FIG. 10 illustrates the second-first mixed layer MM2-1 and the second-second mixed layer MM2-2 as independent and separate layers, however, since the second-first mixed layer MM2-1 and the second-second mixed layer MM2-2 are formed through continuous processes and include the same material, the second mixed layer MM2 may correspond to a single layer.

According to the present disclosure, two types of mixed layers MM1 and MM2 may be sequentially formed by performing one reciprocating movement of the deposition module EM (refer to FIG. 1).

The first mixed layer MM1 may include the first deposition material DM1 (refer to FIG. 1) and the second deposition material DM2 (refer to FIG. 1). The second mixed layer MM2 may include the second deposition material DM2 (refer to FIG. 1) and the third deposition material DM3 (refer to FIG. 1).

The two types of the mixed layers MM1 and MM2 may commonly include the second deposition material DM2 (refer to FIG. 1) discharged from the second deposition source SR2 (refer to FIG. 1).

According to the present disclosure, during one reciprocating movement of the deposition module EM (refer to FIG. 1), a separate mixed layer including the first deposition material DM1 (refer to FIG. 1) and the second deposition material DM2 (refer to FIG. 1) may be prevented from being formed under the second mixed layer MM2.

In addition, during one reciprocating movement of the deposition module EM (refer to FIG. 1), a separate single layer including the first deposition material DM1 (refer to FIG. 1) or the second deposition material DM2 (refer to FIG. 1) may be prevented from being formed.

Accordingly, the reliability of the substrate deposition process to form the two types of mixed layers MM1 and MM2 may be improved, and the cost and time required for the manufacturing process may be reduced.

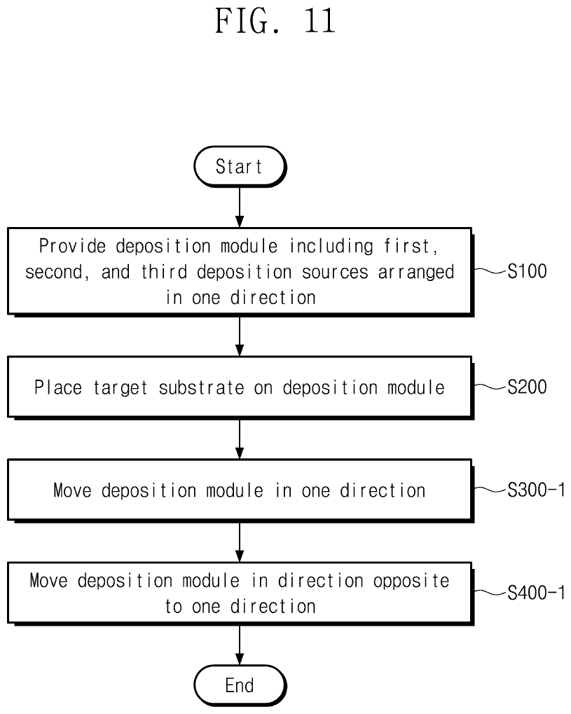

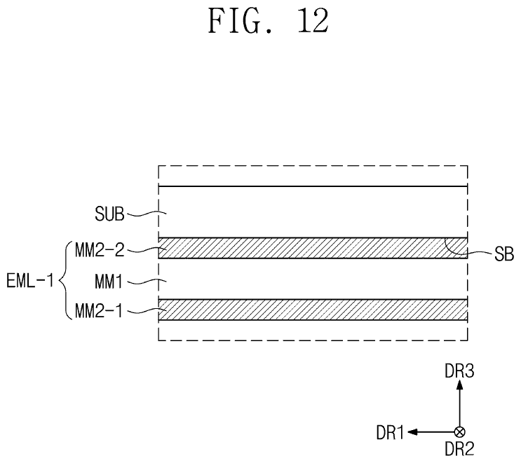

FIG. 11 is a flowchart illustrating a method of manufacturing an electronic device according to an embodiment of the present disclosure. FIG. 12 is an enlarged cross-sectional view illustrating a deposition pattern according to an embodiment of the present disclosure.

Referring to FIG. 11, the manufacturing method of the electronic device according to the present disclosure may include providing a deposition module including first to third deposition sources arranged in one direction (S100), placing a target substrate above the deposition module (S200), moving the deposition module in one direction (S300-1), and moving the deposition module in a direction opposite to the one direction (S400-1).

That is, different from the manufacturing method of the electronic device described with reference to FIG. 3, according to the manufacturing method of the electronic device of the present embodiment, a second movement of the deposition module EM (refer to FIG. 1) may be performed before a first movement.

Referring to FIG. 12, a second-second mixed layer MM2-2, a first mixed layer MM1, and a second-first mixed layer MM2-1 may be sequentially formed on a rear surface SB of the target substrate SUB.

Accordingly, three mixed layers may be sequentially stacked.

Therefore, the reliability of the substrate deposition process to form the three mixed layers MM1, MM2-1, and MM2-2 may be improved, and the cost and time required for the manufacturing process may be reduced.

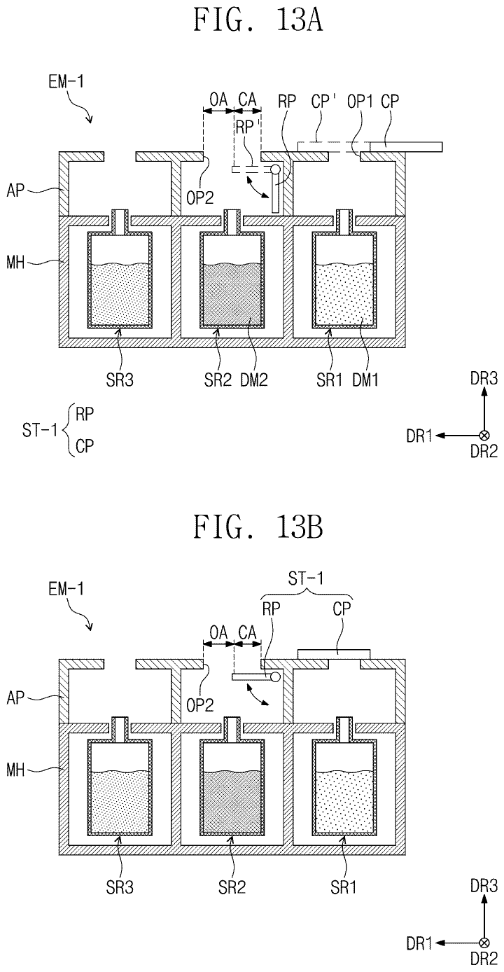

FIGS. 13A and 13B are cross-sectional views illustrating a deposition module according to an embodiment of the present disclosure.

In FIGS. 13A and 13B, the same/similar reference numerals denote the same/similar elements in FIGS. 1 to 9, and thus, descriptions will focus on different features without repeating the same details.

In the present embodiment, the deposition module EM-1 may include a module housing MH, first, second, and third deposition sources SR1, SR2, and SR3, an angle restriction plate AP, and a shutter ST-1.

The shutter ST-1 may include a block plate CP and a rotation plate RP. The shutter ST-1 may block a first opening OP1 and a portion of a second opening OP2 and thus may function to control the discharge of a first deposition material DM1 and the deposition range of a second deposition material DM2.

The shutter ST-1 may operate in a block mode to block the first opening OP1 and the portion of the second opening OP2 or may operate in an open mode to open the first opening OP1 and the second opening OP2. FIG. 13A illustrates a state in which the shutter ST-1 operates in the open mode, and FIG. 13B illustrates a state in which the shutter ST-1 operates in the block mode.

The block plate CP may be disposed on the angle restriction plate AP.

The block plate CP may move in the first direction DR1. In detail, the block plate CP may slide in the first direction DR1.

In the present embodiment, when the shutter ST-1 operates in the block mode, the block plate CP may move in the left direction to block the first opening OP1. When the shutter ST-1 operates in the open mode, the block plate CP may move in the right direction to open the first opening OP1.

The rotation plate RP may be coupled with the angle restriction plate AP. FIGS. 13A and 13B illustrate the structure in which the rotation plate RP is disposed under the second opening OP2 of the angle restriction plate AP as a representative example. However, the position of the rotation plate RP should not be limited to that shown in FIGS. 13A and 13B as long as a block area CA of the second opening OP2 may be opened or blocked. As an example, the rotation plate RP may be disposed on the angle restriction plate AP or may be coupled with a side surface of the angle restriction plate AP, which defines the second opening OP2.

The rotation plate RP may rotate about one direction as its rotation axis to open or block the portion of the second opening OP2. As an example, the rotation plate RP may rotate about 90 degrees with respect to the second direction DR2 as its rotation axis to open or block the block area CA of the second opening OP2.

In the present embodiment, when the shutter ST-1 operates in the block mode, the rotation plate RP may rotate about 90 degrees clockwise from the state shown in FIG. 13A to be positioned at a movement position RP′. Accordingly, the rotation plate RP may block the block area CA as shown in FIG. 13B.

When the shutter ST-1 operates in the open mode, the rotation plate RP may rotate about 90 degrees counterclockwise from the state shown in FIG. 13B to open the block area CA as shown in FIG. 13A.

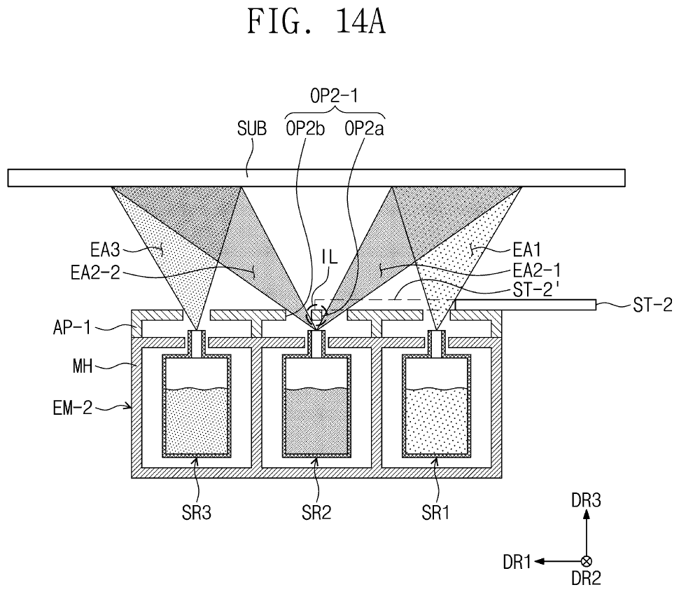

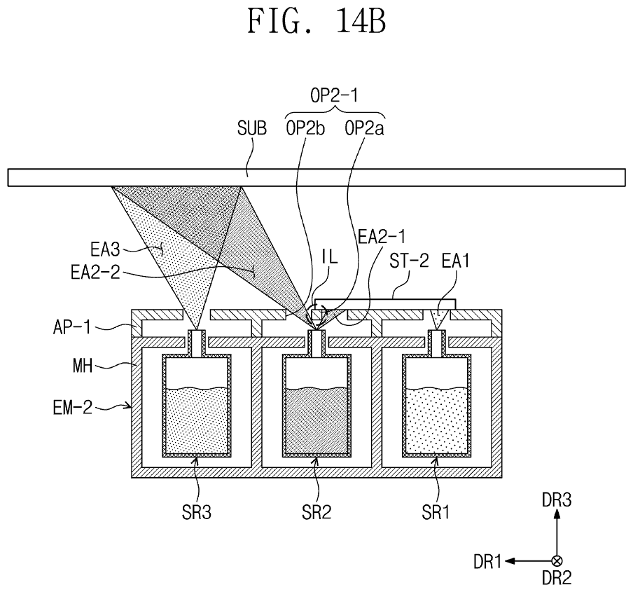

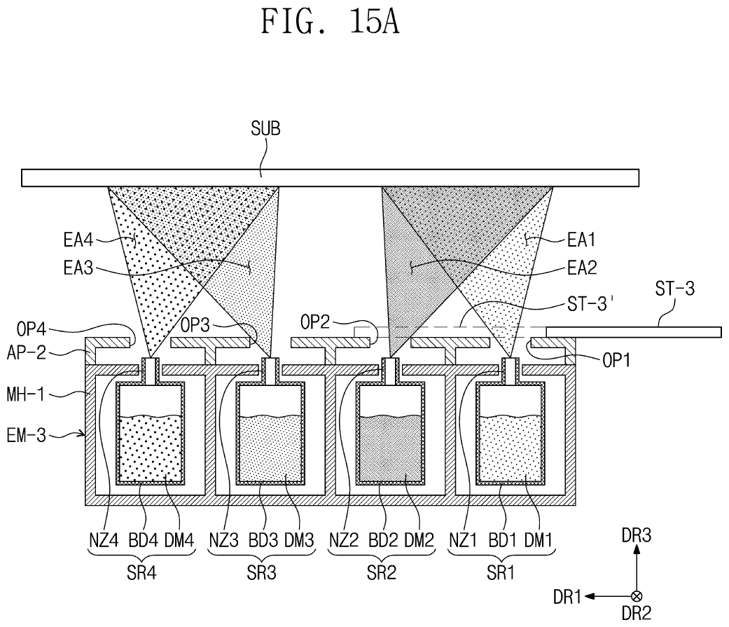

FIGS. 14A and 14B are cross-sectional views illustrating a deposition module according to an embodiment of the present disclosure.

In FIGS. 14A and 14B, the same/similar reference numerals denote the same/similar elements in FIGS. 1 to 9, and thus, descriptions will focus on different features without repeating the same details.

In the present embodiment, the deposition module EM-2 may include a module housing MH, first, second, and third deposition sources SR1, SR2, and SR3, an angle restriction plate AP-1, and a shutter ST-2.

In the present embodiment, a first opening OP1 overlapping the first deposition source SR1, a second opening OP2-1 overlapping the second deposition source SR2, and a third opening OP3 overlapping the third deposition source SR3 may be defined through the angle restriction plate AP-1.

In the present embodiment, the second opening OP2-1 may be divided by a dividing part IL included in the angle restriction plate AP-1. The second opening OP2-1 may include a second-first opening OP2a overlapping an open area OA and a second-second opening OP2b spaced apart from the second-first opening OP2a when viewed in the plane. In detail, when viewed in the plane, the second-first opening OP2a and the second-second opening OP2b may be spaced apart from each other, and the dividing part IL of the angle restriction plate AP-1 may be disposed between the second-first opening OP2a and the second-second opening OP2b.

The shutter ST-2 may operate in a block mode to block the second-first opening OP2a and the first opening OP1 or an open mode to open the second-first opening OP2a and the first opening OP1. FIG. 14A illustrates the open mode of the shutter ST-2, and FIG. 14B illustrates the block mode of the shutter ST-2.

In the present embodiment, the shutter ST-2 may be provided in a block plate shape. The shutter ST-2 may move in the first direction DR1. In detail, the shutter ST-2 may slide in the first direction DR1.

Referring to FIG. 14A, in an area to which a second deposition material (refer to DM2 of FIG. 1) discharged from the second deposition source SR2 is sprayed, an area formed by the second deposition material (refer to DM2 of FIG. 1) passing through the second-first opening OP2a may be referred to as a second-first deposition area EA2-1, and an area formed by the second deposition material (refer to DM2 of FIG. 1) passing through the second-second opening OP2b may be referred to as a second-second deposition area EA2-2.

When the shutter ST-2 operates in the open mode, the second-first deposition area EA2-1 may overlap a first deposition area EA1 to form a first mixed layer (refer to MM1 of FIG. 4), and the second-second deposition area EA2-2 may overlap a third deposition area EA3 to form a second-first mixed layer (refer to MM2-1 of FIG. 6).

When the shutter ST-2 operates in the block mode, the second-second deposition area EA2-2 may overlap the third deposition area EA3 to form a second-second mixed layer (refer to MM2-2 of FIG. 8).

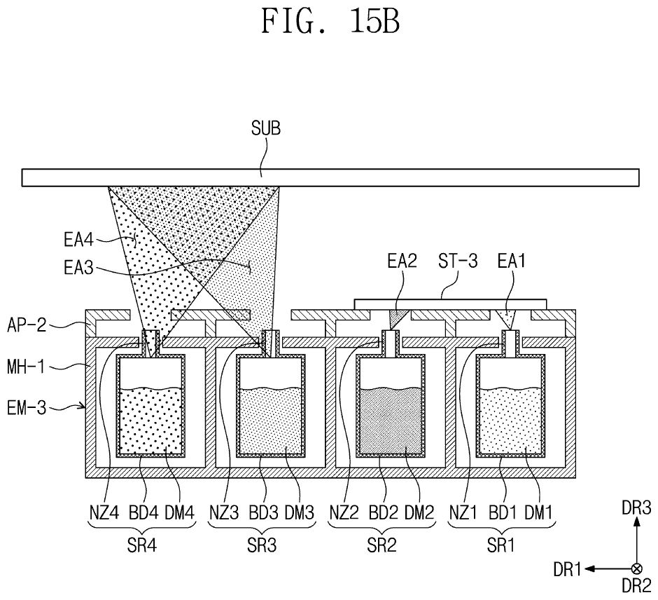

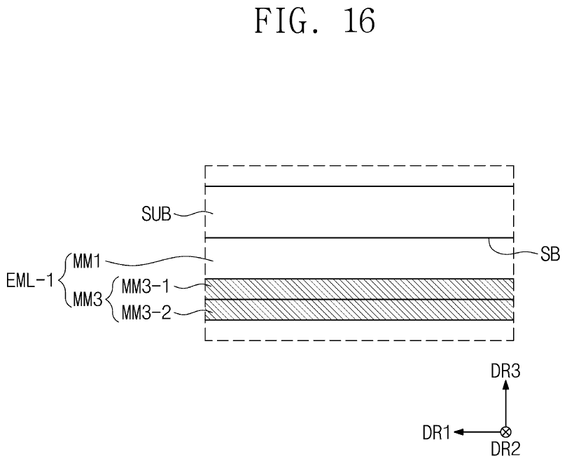

FIGS. 15A and 15B are cross-sectional views illustrating a deposition module according to an embodiment of the present disclosure. FIG. 16 is an enlarged cross-sectional view illustrating a deposition pattern according to an embodiment of the present disclosure.

In FIGS. 15A, 15B, and 16, the same/similar reference numerals denote the same/similar elements in FIGS. 1 to 9, and thus, descriptions will focus on different features without repeating the same details.

In the present embodiment, the deposition module EM-3 may include a module housing MH-1, first, second, third, and fourth deposition sources SR1, SR2, SR3, and SR4, an angle restriction plate AP-2, and a shutter ST-3.

The deposition module EM-3 according to the present embodiment may further include the fourth deposition source SR4 compared to the deposition module EM described with reference to FIGS. 1 to 9.

The fourth deposition source SR4 may include a fourth body part BD4, a fourth nozzle NZ4 disposed on the fourth body part BD4, and a fourth deposition material DM4 disposed in the fourth body part BD4.

The module housing MH-1 may surround the first, second, third, and fourth deposition sources SR1, SR2, SR3, and SR4. The first, second, third, and fourth deposition sources SR1, SR2, SR3, and SR4 may be disposed in the module housing MH-1. However, the present disclosure should not be limited thereto or thereby, and the first, second, third, and fourth deposition sources SR1, SR2, SR3, and SR4 may be provided while being coupled to each other without a separate module housing.

First, second, third, and fourth openings OP1, OP2, OP3, and OP4 may be defined through the angle restriction plate AP-2. When viewed in the plane, the fourth opening OP4 may overlap the fourth deposition source SR4.

The shutter ST-3 may operate in a block mode to block the first opening OP1 and the second opening OP2 or an open mode to open the first opening OP1 and the second opening OP2.

FIG. 16 illustrates a result of a deposition process performed on a rear surface of a target substrate SUB after one first movement of the deposition module EM-3 in the open mode shown in FIG. 15A and one second movement of the deposition module EM-3 in the block mode shown in FIG. 15B. That is, a deposition pattern EML-1 may be formed by one reciprocating movement of the deposition module EM-3.

Referring to FIG. 16, the deposition pattern EML-1 may include a first mixed layer MM1 and a third mixed layer MM3.

The first mixed layer MM1 and a third-first mixed layer MM3-1 may be formed by the first movement of the deposition module EM-3 (refer to FIG. 15A), and a third-second mixed layer MM3-2 may be formed by the second movement of the deposition module EM-3 (refer to FIG. 15B).

The first mixed layer MM1 may include a first deposition material DM1 (refer to FIG. 15A) and a second deposition material DM2 (refer to FIG. 15A).

The third mixed layer MM3 may include the third-first mixed layer MM3-1 and the third-second mixed layer MM3-2.

The third-first mixed layer MM3-1 and the third-second mixed layer MM3-2 may include a third deposition material DM3 (refer to FIG. 15A) and the fourth deposition material DM4 (refer to FIG. 15A). That is, the third-first mixed layer MM3-1 and the third-second mixed layer MM3-2 are separated for the sake of explanation, but the third-first mixed layer MM3-1 and the third-second mixed layer MM3-2 may correspond to a single layer since the third-first mixed layer MM3-1 and the third-second mixed layer MM3-2 are formed through continuous processes and include the same material.

According to the deposition module EM-3 (refer to FIG. 15A) of the present embodiment, two types of mixed layers including different materials from each other are sequentially stacked. In detail, the first mixed layer MM1 including the first and second deposition materials DM1 and DM2 (refer to FIG. 15A) and the third mixed layer MM3 including the third and fourth deposition materials DM3 and DM4 (refer to FIG. 15A) may be sequentially formed.

Accordingly, the process of forming the two types of mixed layers that are sequentially stacked may be simplified, and the manufacturing time and cost required for the electronic device may be reduced.

FIG. 17A is a perspective view illustrating the electronic device manufactured through the manufacturing method of the electronic device according to an embodiment of the present disclosure. FIG. 17B is an exploded perspective view illustrating the electronic device manufactured through the manufacturing method of the electronic device according to an embodiment of the present disclosure.

FIG. 17C is a cross-sectional view illustrating one pixel included in the electronic device.

FIG. 17C illustrates a cross-section of one pixel included in a display panel DP of the electronic device as a representative example.

Referring to FIG. 17A, the electronic device EA may be activated in response to electrical signals and may display images. The electronic device EA may be applied to various embodiments to provide various users with the images. As an example, the electronic device EA may be applied to a large-sized electronic device, such as a television set or an outdoor billboard. In addition, the electronic device EA may be applied to a small and medium-sized electronic device, such as a monitor, a mobile phone, a tablet computer, a navigation unit, a game unit, etc. The electronic device EA may be a foldable display device including a folding area and a non-folding area or a bendable display device including at least one bending portion. However, the electronic device EA should not be particularly limited as long as it does not depart from the inventive concept of the present disclosure.

The electronic device EA may display an image IM through a display surface FS, which is substantially parallel to the plane defined by the first direction DR1 and the second direction DR2, toward the third direction DR3. The third direction DR3 may be substantially parallel to a normal line direction of the display surface FS.

The display surface FS in which the image IM is displayed may correspond to a front surface of the electronic device EA. The image IM may include a still image as well as a video. FIG. 17A shows application icons as a representative example of the image IM.

In the present embodiment, front (or upper) and rear (or lower) surfaces of each member or each unit of the electronic device EA may be defined with respect to a direction in which the image IM is displayed. The front and rear surfaces may be opposite to each other in the third direction DR3, and a normal line direction of each of the front and rear surfaces may be substantially parallel to the third direction DR3. A separation distance between the front and rear surfaces of the member (or the unit) may correspond to a thickness in the third direction DR3 of the member (or the unit).

The front surface FS of the electronic device EA through which the image IM is displayed may correspond to a front surface FS (refer to FIG. 17B) of a window WP (refer to FIG. 17B). Accordingly, the display surface and the front surface of the electronic device EA and the front surface of the window WP will be assigned with the same reference numeral.

Referring to FIG. 17B, the electronic device EA may include the window WP, the display panel DP, and a housing HAU.

The front surface FS of the window WP may include a transmissive area TA and a bezel area BZA. The user may view the image IM (refer to FIG. 17A) provided through the transmissive area TA of the window WP.

The transmissive area TA may be an optically transparent area. The bezel area BZA may be an area having a relatively lower transmittance than the transmissive area TA. The bezel area BZA may have a selected color. The bezel area BZA may be disposed adjacent to the transmissive area TA. FIG. 17B shows a structure in which the bezel area BZA surrounds the transmissive area TA. However, the present disclosure should not be limited thereto or thereby, and the bezel area BZA may be disposed adjacent to only one side of the transmissive area TA.

In FIG. 17B, the transmissive area TA is illustrated as having a quadrangular shape, however, this is merely an example. The transmissive area TA may have a variety of shapes and should not be particularly limited.

The display panel DP may have a configuration that substantially generates the image IM (refer to FIG. 17A). The image IM generated by the display panel DP may be displayed through a display surface IS, and a user may view the image IM through the transmissive area TA.

The display panel DP may include a display area DA and a non-display area NDA adjacent to the display area DA. The display area DA may be activated in response to electrical signals. The non-display area NDA may be covered by the bezel area BZA.

Pixels PX may be arranged in the display area DA. The pixels PX may be arranged in the first and second directions DR1 and DR2.

The housing HAU may accommodate the display panel DP. The housing HAU may cover the display panel DP, and an upper surface of the electronic device EA, i.e., the display surface FS, may be exposed. The housing HAU may cover a side surface and a bottom surface of the display panel DP, and the upper surface may be entirely exposed, however, the present disclosure should not be limited thereto or thereby. According to an embodiment, the housing HAU may cover a portion of the upper surface in addition to the side surface and the bottom surface of the display panel DP.

The display panel DP may include the base substrate BL, a circuit element layer DP-CL, and a display element layer DP-ED.

The base substrate BL may include a flexible plastic substrate. As an example, the base substrate BL may include transparent polyimide (PI).

The circuit element layer DP-CL may be disposed on the base substrate BL.

The circuit element layer DP-CL may include a buffer layer BFL and first, second, third, fourth, and fifth insulating layers 10, 20, 30, 40, and 50.

The buffer layer BFL may be disposed on the base substrate BL. The buffer layer BFL may be an inorganic layer.

A semiconductor pattern may be disposed on the buffer layer BFL. The semiconductor pattern may include polycrystalline silicon, however, it should not be limited thereto or thereby. According to an embodiment, the semiconductor pattern may include amorphous silicon or metal oxide.

The semiconductor pattern may be doped with an N-type dopant or a P-type dopant. The semiconductor pattern may include a high-doped region and a low-doped region. The high-doped region may have a conductivity greater than that of the low-doped region and may substantially serve as a source electrode and a drain electrode of a transistor TR. The low-doped region may substantially correspond to an active (or a channel) of the transistor.

The pixel PX may be disposed on the base substrate BL and may include the transistor TR and the light emitting element OLED. Although not shown in figures, the transistors TR and the light emitting elements OLED of the pixels may be connected to pads through data lines and power lines.

The light emitting element OLED may include a first electrode AE, a second electrode CE, a hole control layer HCL, an electron control layer ECL, and the deposition pattern EML. In the present embodiment, the deposition pattern EML may be referred to as the light emitting layer. The first electrode AE may be an anode electrode, and the second electrode CE may be a cathode electrode.

The transistor TR and the light emitting element OLED may be disposed on the base substrate BL. As an example, one transistor TR is illustrated, however, the pixel may include a plurality of transistors and at least one capacitor to drive the light emitting element OLED.

The display area DA may include a light emitting area PA corresponding to the pixel and a non-light-emitting area NPA around the light emitting area PA. The light emitting element OLED may be disposed in the light emitting area PA.

A source S-D, an active A-D, and a drain D-D of the transistor TR may be formed from the semiconductor pattern. The first insulating layer 10 may be disposed on the semiconductor pattern. A gate G-D of the transistor TR may be disposed on the first insulating layer 10. The second insulating layer 20 may be disposed on the gate G-D. The third insulating layer 30 may be disposed on the second insulating layer 20.

A connection electrode CNE may include a first connection electrode CNE1 and a second connection electrode CNE2. The connection electrodes CNE1 and CNE2 may be disposed between the transistor TR and the light emitting element OLED to connect the transistor TR and the light emitting element OLED.

The first connection electrode CNE1 may be disposed on the third insulating layer 30 and may be connected to the drain D-D via a first contact hole CNT-1 defined through the first, second, and third insulating layers 10, 20, and 30. The fourth insulating layer 40 may be disposed on the first connection electrode CNE1.

The second connection electrode CNE2 may be disposed on the fourth insulating layer 40. The second connection electrode CNE2 may be connected to the first connection electrode CNE1 via a second contact hole CNT-2 defined through the fourth insulating layer 40.

The fifth insulating layer 50 may be disposed on the second connection electrode CNE2. Each of the first to fifth insulating layers 10 to 50 may be an inorganic layer or an organic layer.

The first electrode AE may be disposed on the fifth insulating layer 50. The first electrode AE may be connected to the second connection electrode CNE2 via a third contact hole CNT-3 defined through the fifth insulating layer 50. A pixel definition layer PDL through which a portion of the first electrode AE is exposed may be disposed on the first electrode AE and the fifth insulating layer 50. An opening PX_OP may be defined through the pixel definition layer PDL to expose the portion of the first electrode AE.

The hole control layer HCL may be disposed on the first electrode AE and the pixel definition layer PDL. The hole control layer HCL may be commonly disposed in the light emitting area PA and the non-light-emitting area NPA. The hole control layer HCL may include a hole transport layer and a hole injection layer.

The light emitting layer EML may be disposed on the hole control layer HCL. The light emitting layer EML may be disposed in an area corresponding to the opening PX_OP. The light emitting layer EML may include an organic material or an inorganic material. The light emitting layer EML may generate a light having one of red, green, and blue colors.

The electron control layer ECL may be disposed on the light emitting layer EML and the hole control layer HCL. The electron control layer ECL may be commonly disposed in the light emitting area PA and the non-light-emitting area NPA. The electron control layer ECL may include an electron transport layer and an electron injection layer.

The second electrode CE may be disposed on the electron control layer ECL. The second electrode CE may be commonly disposed over the pixels PX. Layers from the buffer layer BFL to the light emitting element OLED may be referred to as a pixel layer.

A thin film encapsulation layer TFE may be disposed on the light emitting element OLED. The thin film encapsulation layer TFE may be disposed on the second electrode CE to cover the pixel. The thin film encapsulation layer TFE may include at least two inorganic layers and an organic layer disposed between the inorganic layers. The inorganic layers may protect the pixel from moisture and oxygen. The organic layer may protect the pixel from a foreign substance such as dust particles.

A first voltage may be applied to the first electrode AE via the transistor TR, and a second voltage having the level lower than the first voltage may be applied to the second electrode CE. Holes and electrons injected into the light emitting layer EML may be recombined to generate excitons, and the light emitting element OLED may emit the light by the excitons that return to a ground state from an excited state.

FIG. 17D is a block diagram illustrating the electronic device according to an embodiment of the present disclosure.

Referring to FIG. 17D, the electronic device EA may communicate with an external electronic device 102 through a network (for example, a short-range wireless communication network or a long-range wireless communication network). According to an embodiment, the electronic device EA may include a processor 110, a memory 120, an input module 130, a display module DM, a power module 150, an internal module 160, and an external module 170. According to an embodiment, in the electronic device EA, at least one of the above-described components may be omitted or one or more other components may be added. According to an embodiment, some of the above-described components may be integrated into another component (for example, the display module DM).

The processor 110 may execute software to control at least another component (for example, a hardware or software component) of the electronic device EA connected to the processor 110 and may perform various data processing or operations. According to an embodiment, as at least a portion of the data processing or operations, the processor 110 may store commands or data received from other components (for example, the input module 130, the sensor module 161, or a communication module 173) in a volatile memory 121, may process the commands or the data stored in the volatile memory 121, and may store result data in a nonvolatile memory 122.

The processor 110 may include a main processor 111 and an auxiliary processor 112. The main processor 111 may include one or more of a central processing unit (CPU) 111-1 or an application processor (AP). The main processor 111 may further include any one or more of a graphics processing unit (GPU) 111-2, a communication processor (CP), and an image signal processor (ISP).

The main processor 111 may further include a neural processing unit (NPU) 111-3. The NPU is a processor specialized in processing an artificial intelligence model, and the artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted boltzmann machine (RBM), a deep belief network (DBN), a bidirectional recurrent deep neural network (BRDNN), a deep Q-network, or a combination of two or more of the above, but is not limited to the above-described example. Additionally or alternatively, the artificial intelligence model may include a software structure in addition to a hardware structure. At least two of the above-described processing units and processors may be implemented as a single integrated component (for example, a single chip) or as separate components (for example, a plurality of chips).

The auxiliary processor 112 may include a controller 112-1. The controller 112-1 may include an interface conversion circuit and a timing control circuit. The controller 112-1 may receive an image signal from the main processor 111, convert a data format of the image signal to correspond to an interface specification with the display module DM, and output image data. The controller 112-1 may output various control signals necessary for driving the display module DM.

The auxiliary processor 112 may further include a data conversion circuit 112-2, a gamma correction circuit 112-3, a rendering circuit 112-4, and the like. The data conversion circuit 112-2 may receive the image data from the controller 112-1, compensate for the image data to display an image with a desired luminance based on characteristics of the electronic device EA, user settings, or the like, or convert the image data to reduce power consumption or to compensate for image retention.

The gamma correction circuit 112-3 may convert the image data, a gamma reference voltage, or the like so that the image displayed on the electronic device EA has a desired gamma characteristic. The rendering circuit 112-4 may receive the image data from the controller 112-1 and render the image data taking into account a pixel arrangement or the like of a display panel DP applied to the electronic device EA.

At least one of the data conversion circuit 112-2, the gamma correction circuit 112-3, and the rendering circuit 112-4 may be integrated into another component (for example, the main processor 111 or the controller 112-1). At least one of the data conversion circuit 112-2, the gamma correction circuit 112-3, and the rendering circuit 112-4 may be integrated into a data driver DDV, which is described later. Although not shown in the drawing, the data driver DDV may be a portion of a circuit included in a driving chip.

The memory 120 may store various data used by at least one component (for example, the processor 110 or the sensor module 161) of the electronic device EA and input or output data related to corresponding commands. The memory 120 may include at least one of the volatile memory 121 and the nonvolatile memory 122.

The input module 130 may receive commands or data to be used by a component (for example, the processor 110, the sensor module 161, or the audio output module 163) of the electronic device EA from an external source (for example, the user or the external electronic device 102) of the electronic device EA.

The input module 130 may include a first input module 131 receiving commands or data from the user and a second input module 132 receiving commands or data from the external electronic device 102. The first input module 131 may include a microphone, a mouse, a keyboard, a key (for example, a button), or a pen (for example, a passive pen or an active pen).

The second input module 132 may support a designated protocol that enables connection to the external electronic device 102 via a wired or wireless connection. According to an embodiment, the second input module 132 may include a high definition multimedia interface (HDMI), a universal serial bus (USB) interface, an SD card interface, or an audio interface. The second input module 132 may include a connector capable of physically connecting to the external electronic device 102, for example, an HDMI connector, a USB connector, an SD card connector, or an audio connector (for example, a headphone connector).

The display module DM may provide visual information to the user. The display module DM may include the display panel DP, a scan driver SDV, and the data driver DDV. The display module DM may further include a window, a chassis, and a bracket to protect the display panel DP.

The display panel DP may include a liquid crystal display panel, an organic light emitting display panel, or an inorganic light emitting display panel, and a type of the display panel DP should not be particularly limited. The display panel DP may be a rigid type or a flexible type that may be rolled or folded. The display module DM may further include a supporter, a bracket, a heat dissipation member, or the like that supports the display panel DP.

The scan driver SDV may be mounted on the display panel DP as a driving chip. In addition, the scan driver SDV may be integrated in the display panel DP. For example, the scan driver SDV may include an amorphous silicon TFT gate driver circuit (ASG), a low temperature polycrystalline silicon (LTPS) TFT gate driver circuit, or an oxide semiconductor TFT gate driver circuit (OSG) built in the display panel DP. The scan driver SDV may receive a control signal from the controller 112-1 and output scan signals to the display panel DP in response to the control signal.

The display panel DP may further include an emission driver. The emission driver may output an emission control signal to the display panel DP in response to a control signal received from the controller 112-1. The emission driver may be formed separately from the scan driver SDV or may be integrated into the scan driver SDV.

The data driver DDV may receive a control signal from the controller 112-1, convert image data into an analog voltage (for example, a data voltage) in response to the control signal, and then output the data voltages to the display panel DP.

The data driver DDV may be integrated into another component (for example, the controller 112-1). A function of the interface conversion circuit and the timing control circuit of the controller 112-1 described above may be integrated into the data driver DDV.

The display module DM may further include the emission driver, a voltage generation circuit, and the like. The voltage generation circuit may output various voltages necessary for driving the display panel DP.

The power module 150 may supply power to components of the electronic device EA. The power module 150 may include a battery that charges a power voltage. The battery may include a non-rechargeable primary cell, a rechargeable secondary cell, or fuel cell. The power module 150 may include a power management integrated circuit (PMIC). The PMIC may supply optimized power to each of the above-described modules and modules described later. The power module 150 may include a wireless power transmission/reception member electrically connected to the battery. The wireless power transmission/reception member may include a plurality of antenna radiators of a coil form.

The electronic device EA may further include the internal module 160 and the external module 170. The internal module 160 may include the sensor module 161, the antenna module 162, and the audio output module 163. The external module 170 may include a camera module 171, a light module 172, and the communication module 173.

The sensor module 161 may sense an input by a body of the user or an input by a pen among the first input module 131 and may generate an electrical signal or a data value corresponding to the input. The sensor module 161 may include at least one of a fingerprint sensor 161-1, an input sensing layer 161-2, and a digitizer 161-3.

The fingerprint sensor 161-1 may generate a data value corresponding to a fingerprint of the user. The fingerprint sensor 161-1 may include any one of an optical type fingerprint sensor or a capacitive type fingerprint sensor.

The input sensing layer 161-2 may generate a data value corresponding to coordinate information of the input by the body of the user or the input by the pen. The input sensing layer 161-2 may generate the data value based on the change in capacitance caused by the input. The input sensing layer 161-2 may sense an input by the passive pen or may transmit/receive data to and from the active pen.

The input sensing layer 161-2 may measure a biometric signal such as blood pressure, hydration levels, or body fat. For example, when the user touches a part of their body to a sensor layer or a sensing panel and remains still for a certain period, the input sensing layer 161-2 may sense the biometric signal based on changes in an electric field caused by the body part and output information desired by the user to the display module DM.

The digitizer 161-3 may generate a data value corresponding to coordinate information of the input by the pen. The digitizer 161-3 may generate the data value based on changes in an electromagnetic field caused by the input. The digitizer 161-3 may sense the input by the passive pen or may transmit/receive data to and from the active pen.

At least one of the fingerprint sensor 161-1, the input sensing layer 161-2, and the digitizer 161-3 may be implemented as a sensor layer formed on the display panel DP through a continuous process. The fingerprint sensor 161-1, the input sensing layer 161-2, and the digitizer 161-3 may be disposed above the display panel DP, and any one of the fingerprint sensor 161-1, the input sensing layer 161-2, and the digitizer 161-3, for example, the digitizer 161-3 may be disposed below the display panel DP.

At least two of the fingerprint sensor 161-1, the input sensing layer 161-2, and the digitizer 161-3 may be integrated into a single sensing panel through the same process. When at least two of the fingerprint sensor 161-1, the input sensing layer 161-2, and the digitizer 161-3 are integrated into one sensing panel, the sensing panel may be disposed between the display panel DP and the window disposed above the display panel DP. According to an embodiment, the sensing panel may be disposed on the window, and a position of the sensing panel should not be particularly limited.

At least one of the fingerprint sensor 161-1, the input sensing layer 161-2, and the digitizer 161-3 may be embedded in the display panel DP. That is, at least one of the fingerprint sensor 161-1, the input sensing layer 161-2, and the digitizer 161-3 may be simultaneously formed through a process of forming elements (for example, a light emitting element, a transistor, and the like) included in the display panel DP.

In addition, the sensor module 161 may generate an electrical signal or a data value corresponding to an internal state or an external state of the electronic device EA. The sensor module 161 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 162 may include one or more antennas to transmit a signal or power to an external source or to receive a signal or power from the external source. According to an embodiment, the communication module 173 may transmit a signal to an external electronic device or may receive a signal from an external electronic device through an antenna suitable for a communication method. An antenna pattern of the antenna module 162 may be integrated into one component (for example, the display panel DP) of the display module DM or the input sensing layer 161-2.

The audio output module 163 is a device to output an audio signal to an outside of the electronic device EA and, for example, may include a speaker used for general purposes such as multimedia playback or recording playback and a receiver used exclusively to receive a phone call. According to an embodiment, the receiver may be formed integrally with or separately from the speaker. An audio output pattern of the audio output module 163 may be integrated into the display module DM.

The camera module 171 may capture a still image and a video. According to an embodiment, the camera module 171 may include one or more lenses, an image sensor, or an image signal processor. The camera module 171 may further include an infrared camera capable of measuring presence or absence of the user, a position of the user, a gaze of the user, and the like.

The light module 172 may provide light. The light module 172 may include a light emitting diode or a xenon lamp. The light module 172 may operate in conjunction with the camera module 171 or may operate independently.

The communication module 173 may support the establishment of a wired or wireless communication channel between the electronic device EA and the external electronic device 102 and communication through the established communication channel. The communication module 173 may include one or both of a wireless communication module such as a cellular communication module, a short-range wireless communication module, or a global navigation satellite system (GNSS) communication module and a wired communication module such as a local area network (LAN) communication module or a power line communication module. The communication module 173 may communicate with the external electronic device 102 through a short-range communication network such as Bluetooth, WiFi direct, or infrared data association (IrDA), or a long-range communication network such as a cellular network, the Internet, or a computer network (for example, LAN or WAN). The above-described various types of communication modules 173 may be implemented as a single chip or as separate chips.

The input module 130, the sensor module 161, the camera module 171, and the like may be used in conjunction with the processor 110 to control an operation of the display module DM.

The processor 110 may output commands or data to the display module DM, the audio output module 163, the camera module 171, or the light module 172 based on input data received from the input module 130. For instance, the processor 110 may generate image data in response to the input data applied through the mouse, the active pen, or the like and output the image data to the display module DM or may generate command data in response to the input data and output the command data to the camera module 171 or the light module 172. When no input data is received from the input module 130 for a certain period of time, the processor 110 may switch an operation mode of the electronic device EA to a low power mode or a sleep mode to reduce power consumed in the electronic device EA.

The processor 110 may output commands or data to the display module DM, the audio output module 163, the camera module 171, or the light module 172 based on sensing data received from the sensor module 161. For instance, the processor 110 may compare authentication data applied by the fingerprint sensor 161-1 with authentication data stored in the memory 120 and then execute an application according to a comparison result. The processor 110 may execute the command based on sensing data sensed by the input sensing layer 161-2 or the digitizer 161-3 or may output corresponding image data to the display module DM. When the sensor module 161 includes a temperature sensor, the processor 110 may receive temperature data measured by the sensor module 161 and further perform luminance correction or the like to the image data based on the temperature data.

The processor 110 may receive measurement data regarding the presence or absence of the user, the position of the user, the gaze of the user, and the like, from the camera module 171. The processor 110 may further perform luminance correction or the like to the image data based on the measurement data. For instance, when the processor 110 determines the presence or absence of the user through an input from the camera module 171, the processor 110 may output image data whose luminance is corrected through the data conversion circuit 112-2 or the gamma correction circuit 112-3 to the display module DM.

Among the above-described components, some components may be connected to each other through a communication method between peripheral devices, for example, a bus, general purpose input/output (GPIO), a serial peripheral interface (SPI), a mobile industry processor interface (MIPI), or an ultra-path interconnect (UPI) link to exchange a signal (for example, commands or data) with each other. The processor 110 may communicate with the display module DM through a mutually agreed interface, for example, any one of the above-described communication methods, and the communication method should not be limited to the above-described communication method.

The electronic device EA according to various embodiments of the present disclosure may be applied to various types of devices. The electronic device EA may include, for example, at least one of a portable communication device (e.g., a smartphone), a computer device, a portable multimedia device, a portable medical device, a camera, a wearable device, and a home appliance device. The electronic device EA according to various embodiments of the present disclosure should not be limited to the above-described devices.

FIG. 18 is a cross-sectional view illustrating a deposition process performed by the deposition apparatus of FIG. 1.

FIG. 18 is a view illustrating a process of the manufacturing method of the electronic device shown in FIG. 17A.

Referring to FIG. 18, the components from the base substrate BL to the hole control layer HCL may correspond to the target substrate SUB shown in FIG. 1.

The mask MK (refer to FIG. 1) may be disposed to face the target substrate SUB (refer to FIG. 1). The mask MK (refer to FIG. 1) may be disposed adjacent to the target substrate SUB (refer to FIG. 1).

The deposition material DM may be provided onto the target substrate SUB through the mask opening MK-OP. The light emitting layer EML may be formed on the target substrate SUB by the deposition material DM.

In the present embodiment, the light emitting layer EML may include the first mixed layer MM1 and the second mixed layer MM2, which are sequentially stacked in the third direction DR3.

The first mixed layer MM1 may include the first deposition material DM1 (refer to FIG. 1) and the second deposition material DM2 (refer to FIG. 1), and the second mixed layer MM2 may include the second deposition material DM2 (refer to FIG. 1) and the third deposition material DM3 (refer to FIG. 1). As an example, the first mixed layer MM1 may include the first host material and the dopant material, and the second mixed layer MM2 may include the second host material and the dopant material.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present inventive concept shall be determined according to the attached claims.

What is claimed is:

1. A deposition apparatus comprising:
a chamber having an inner space; and
a deposition module disposed in the inner space, movable in a first direction, and comprising a first deposition source, a second deposition source, a third deposition source, an angle restriction plate through which a first opening overlapping the first deposition source when viewed in a plane, a second opening overlapping the second deposition source when viewed in the plane and comprising an open area and a block area, and a third opening overlapping the third deposition source when viewed in the plane are defined, and a shutter configured to operate in a block mode to block the block area and the first opening, and in an open mode to open the first opening and the second opening.

2. The deposition apparatus of claim 1, wherein the second opening has a width greater than each of a width of the first opening and a width of the third opening when viewed in a cross-section.

3. The deposition apparatus of claim 1, wherein the first deposition source includes a first deposition material, the second deposition source includes a second deposition material, and the third deposition source includes a third deposition material, and
a second discharge angle at which the second deposition material passes through the second opening is greater than a first discharge angle at which the first deposition material passes through the first opening and a third discharge angle at which the third deposition material passes through the third opening.

4. The deposition apparatus of claim 1, wherein the first deposition source, the second deposition source, and the third deposition source are sequentially arranged in the first direction.

5. The deposition apparatus of claim 1, wherein the block area is defined closer to the first opening than the opening area.

6. The deposition apparatus of claim 3, wherein the second deposition material is different from the first deposition material and the third deposition material.

7. The deposition apparatus of claim 6, wherein the first deposition material comprises a first host material, the second deposition material comprises a dopant material, and the third deposition material comprises a second host material.

8. The deposition apparatus of claim 1, wherein the first deposition source comprises a first body part and a first nozzle disposed on the first body part, the second deposition source comprises a second body part and a second nozzle disposed on the second body part, and the third deposition source comprises a third body part and a third nozzle disposed on the third body part.

9. The deposition apparatus of claim 1, wherein the shutter has a block plate shape that is movable in the first direction, and when the shutter operates in the block mode, the shutter blocks the block area and the first opening.

10. The deposition apparatus of claim 9, wherein the shutter is slidable in the first direction.

11. The deposition apparatus of claim 1, wherein the shutter comprises a block plate that is movable in the first direction and a rotation plate that is attached to the angle restriction plate, and when the shutter operates in the block mode, the block plate blocks the first opening, and the rotation plate blocks the block area.

12. The deposition apparatus of claim 1, wherein the second opening comprises a second-first opening overlapping the open area and a second-second opening spaced apart from the second-first opening and overlapping the block area when viewed in the plane.

13. A deposition apparatus comprising:
a chamber having an inner space; and
a deposition module disposed in the inner space, movable in a first direction, and comprising a first deposition source, a second deposition source, a third deposition source, a fourth deposition source, an angle restriction plate through which first, second, third, and fourth openings respectively overlapping the first, second, third, and fourth deposition sources when viewed in a plane are defined, and a shutter configured to operate in a block mode to block the first opening and the second opening, and in an open mode to open the first opening and the second opening, and
wherein the shutter has a block plate shape that is movable in the first direction, and the shutter is slidable in the first direction.

14. A method of manufacturing an electronic device, comprising:
providing a deposition module comprising first, second, and third deposition sources sequentially arranged in one direction, an angle restriction plate through which first, second, and third openings respectively overlapping the first, second, and third deposition sources when viewed in a plane are defined, and a shutter blocking a deposition process by the first and second deposition sources;
placing a target substrate above the deposition module;
operating the deposition module to form a first mixed layer comprising a first deposition material provided from the first deposition source and a second deposition material provided from the second deposition source on a rear surface of the target substrate, to form a second-first mixed layer comprising the second deposition material and a third deposition material provided from the third deposition source on a rear surface of the first mixed layer, and to move in a direction opposite to the one direction; and
operating the shutter to block a portion of the second opening and the first opening and allowing the deposition module to form a second-second mixed layer comprising the second deposition material provided from the second deposition source and the third deposition material provided from the third deposition source on a rear surface of the second-first mixed layer and to move in the one direction.

15. The method of claim 14, further comprising allowing the shutter to block the portion of the second opening and the first opening and allowing the deposition module to form the second-second mixed layer comprising the second deposition material provided from the second deposition source and the third deposition material provided from the third deposition source on the rear surface of the second-first mixed layer and to move in the one direction between the placing of the target substrate above the deposition module and the moving of the deposition module in the direction opposite to the one direction.

16. The method of claim 14, wherein the first deposition source comprises a first nozzle facing the target substrate, and when the moving of the deposition module in the direction opposite to the one direction starts, the first nozzle is positioned in the one direction beyond a side surface of the target substrate adjacent to the deposition module.

17. The method of claim 14, wherein the second opening has a width greater than a width of the first opening and a width of the third opening when viewed in a cross-section, and a second discharge angle at which the second deposition material passes through the second opening is greater than a first discharge angle at which the first deposition material passes through the first opening and a third discharge angle at which the third deposition material passes through the third opening.

18. The method of claim 14, wherein areas where the first, second, and third deposition materials are deposited on the rear surface of the target substrate after respectively passing through the first, second, and third openings are defined as first, second, and third deposition areas, respectively, in the moving of the deposition module in the direction opposite to the one direction, the second deposition area overlaps the first deposition area and the third deposition area, and the first deposition area is spaced apart from the third deposition area with a gap.

19. The method of claim 14, wherein a second deposition area formed by the second deposition material passing through the second opening overlaps a third deposition area formed by the third deposition material passing through the third opening in the moving of the deposition module in the one direction.

20. An electronic device comprising:
a display panel comprising pixels;
a window disposed on the display panel; and
a housing disposed on a rear surface of the display panel, each of the pixels comprising a display element comprising a light emitting layer and a pixel driving circuit, wherein the light emitting layer is formed by the method of claim 15.
